(19) United States
(12) Patent Application Publication
(10) Pub. No.: US 2004/0082159 A1
(43) Pub. Date: Apr. 29, 2004

(54) Fabrication method for solder bump pattern of rear section wafer package

(76) Inventors: Wen-Lo Shieh, Taipei (TW); Fu-Yu Huang, Taipei (TW); Ning Huang, Taipei (TW); Hui-Pin Chen, Taipei (TW); Shu-Wan Lu, Taipei (TW); Zhe-Sung Wu, Taipei (TW); Chih-Yu Tsai, Taipei (TW); Mei-Hua Chen, Taipei (TW); Chia-Ling Lu, Taipei (TW); Yu-Ju Wang, Taipei (TW); Yu-Chun Huang, Taipei (TW); Tzu-Lin Liu, Taipei (TW); Wen-Tsung Weng, Taipei (TW); Ya-Hsin Tseng, Taipei (TW)

Correspondence Address: Wen Lo Shieh, PO Box 82-144, Taipei, TW

(21) Appl. No.: 10/383,757

(22) Filed: Mar. 10, 2003

(30) Foreign Application Priority Data
Oct. 23, 2002 (TW) 091125382

(51) Int. Cl. H01L 21/44

(52) U.S. Cl. 438/612

(57) ABSTRACT

A fabrication method for solder bump pattern of rear section wafer package is disclosed and the method includes the steps of: (a) pattern-etching the wafer at a passivation layer for the positioning of the solder bump; (b) depositing the entire under bump metal layer,

(c) performing an opening on a solder pad using a photoresistor of an appropriate thickness; (d) placing the wafer at a vacuuming system and a heating system, where at this instance, the solder is in a liquid state having a fluidity but without formation of bubbles; and (e) forming a solder bump pattern at the opening position of the photoresistor of under bump metal of the wafer.

### BACKGROUND OF THE INVENTION

1. (a) Technical Field of the Invention

The present invention relates to a fabrication method for solder bump pattern, and in particular, a method employing appropriate vacuum heating system to fabricate solder bump pattern for the backend wafer level package.

2. (b) Description of the Prior Art

Conventional method of fabricating solder bump for wafer is by first forming pattern on the solder pad master 11′ of the solder bump 14′ and the passivation layer 12′ on the wafer 1′, and then depositing under bump metal 13′ and covering the wafer with a photoresistor 2′, and forming an opening 21′ on the solder pad 11′, and forming a solder bump 14′ on the opening 21′ position. The method of forming solder bump 14′ can be electroplated method or silk screening printing method or impregnation. The silk screening printing method is a more efficient method as compared to electroplating method. However in the method of silk screening printing or impregnation method, due to the fluidity of the solder or soldering aid 3′ and the shape of the opening 21′ of the photoresistor 2′ for the filing of the solder or solder aid 3′ will cause residual bubbles at the wall of the opening 21′. If the bubbles are covered by the solder or solder aid 3′, they will not be easily discharged. Upon cooling of the solder aid 3′, the yield of the solder bump 14′ will be affected.

In view of the above drawbacks in the conventional methods, it is an object of the present invention to provide a fabrication method for solder bump pattern of rear section wafer package to mitigate the shortcomings.

### SUMMARY OF THE INVENTION

Accordingly, it is an object of the present invention to provide a fabrication method for solder bump pattern of rear section wafer package, comprising the steps of:

(a) pattern-etching the wafer at a passivation layer for the positioning of the solder bump;

(b) depositing the entire under bump metal layer;

(c) performing an opening on a solder pad using a photoresistor of an appropriate thickness;

(d) placing the wafer at a vacuuming system and a heating system, where at this instance, the solder is at a melting state having a fluidity but without formation of bubbles; and

(e) forming a solder bump pattern at the opening position of the photoresistor of under bump metal of the wafer.

A further object of the present invention is to provide a fabrication method for solder bump pattern of rear section wafer level package, wherein the formation of the solder bump on the wafer comprises the steps of:

(a) placing the wafer at a sloping position into a solder bath within a vacuuming system and the surface position of the solder bath is provided with a squeegee to contact the surface of the wafer, and the wafer being withdrawn and the solder being squeezed into the photo-resistor opening and the excessive solder being scraped off;

(b) removing the wafer from the vacuuming system and the heating system, and after the wafer being cooled, removing the photo-resistor to retain the solder ingot at under bump metal and further etching the under bump metal between the solder ingots so that the solder ingots are isolated into separate one;

(c) performing a wafer reflow to a melting furnace step to melt the solder ingot into a spherical solder bump.

Yet another object of the present invention is to provide a fabrication method for solder bump pattern of rear section wafer package, wherein the formation of solder bump on the wafer comprises the steps of:

(a) horizontally placing the wafer in a vacuuming system and heating system and melted solder being squeezed from one end to the other end of the wafer such that the solder fills the photo-resistor opening position of an under bump metal layer;

(b) removing the wafer from the vacuuming system and the heating system, and after the wafer being cooled, removing the photo-resistor to retain the solder ingot at under bump metal and further etching the under bump metal between the solder ingots so that the solder ingots are isolated into separate one;

(c) performing a wafer reflow to a melting furnace step to melt the solder ingot into a spherical solder bump.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view showing the conventional method of fabrication of solder bump.

FIGS. 2A to 2D are schematic flowcharts of forming wafer solder bump in accordance with the present invention.

FIGS. 3A to 3C are schematic flowcharts of forming wafer solder bump by silk-screening method in accordance with the present invention.

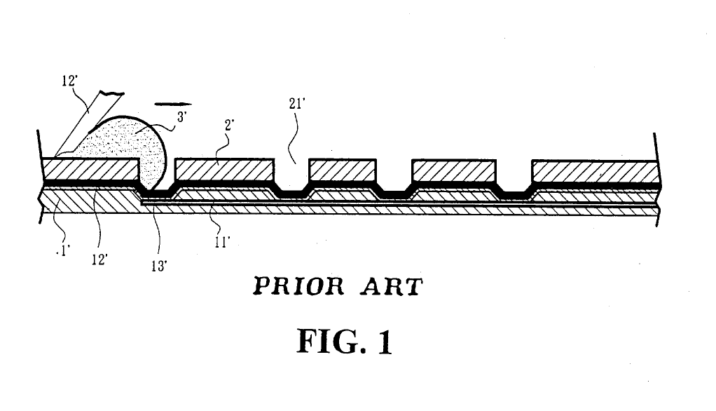

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

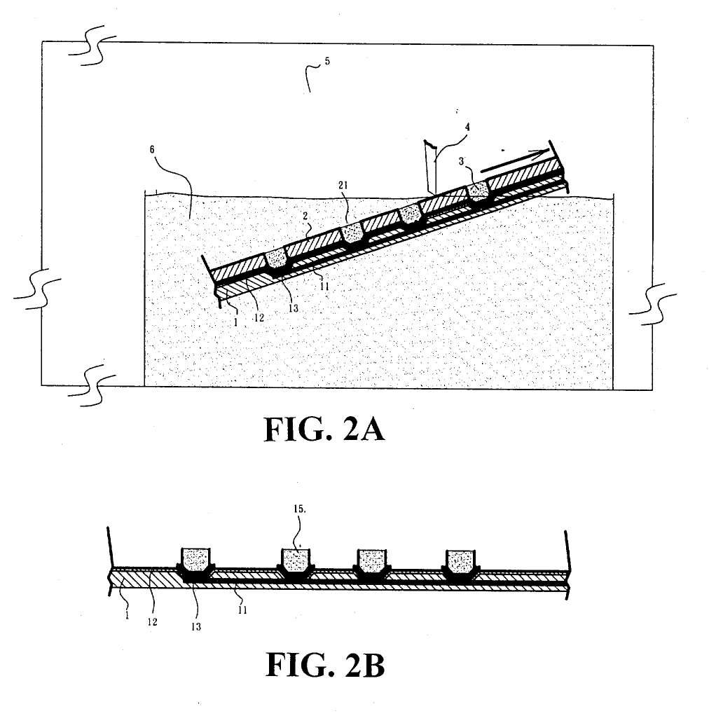

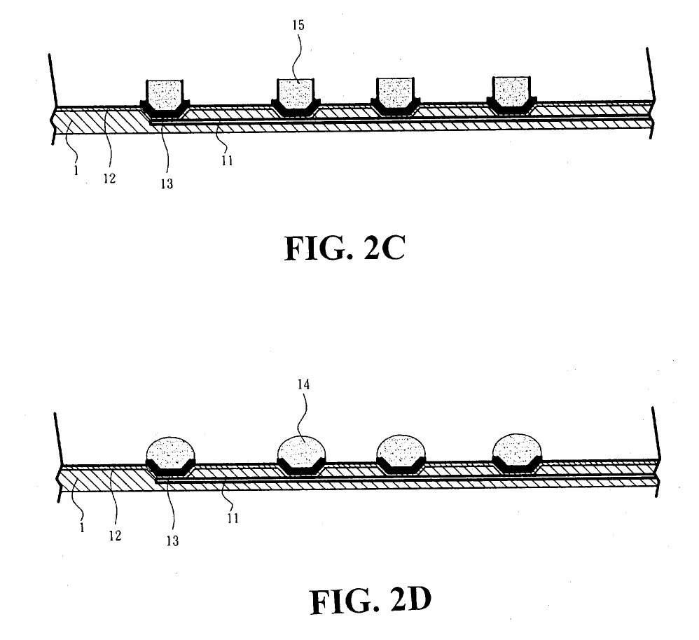

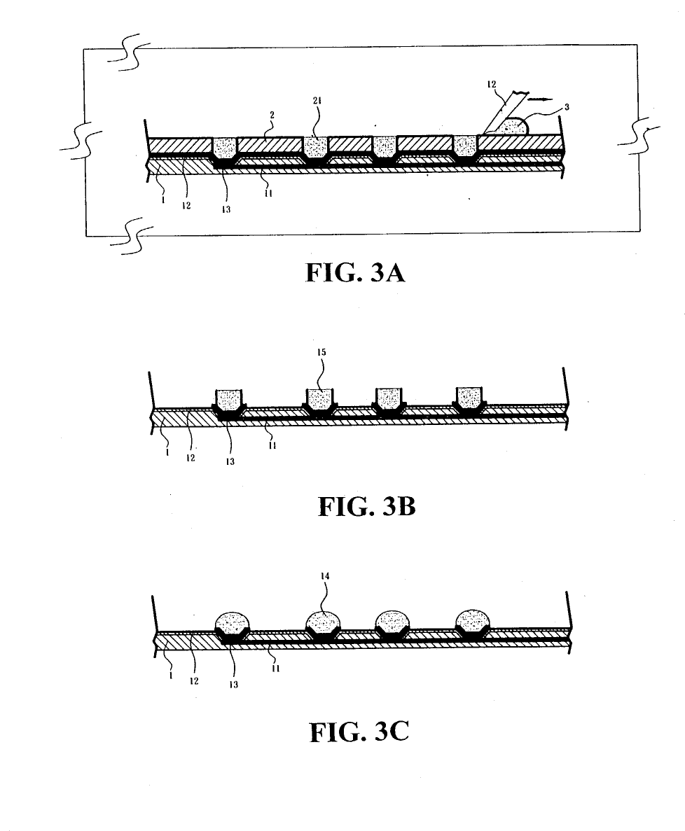

In accordance with the present invention, and as shown in FIG. 2, there is shown a method of fabrication of solder bump.

A wafer 1 which has been etched to form pattern is placed onto the solder pad 11 of a passivation layer 12. The under bump metal layer 13 has been fully deposited and on the solder pad 11, an appropriate thickness of photo-resistor 2 is used to produce an opening 21. The wafer 1 is placed within a vacuum and heating system 5. The solder 3 is in the liquid state such that the solder 3 has fluidity and will not produce bubbles. The opening 21 position of the photo-resistor 2 is formed into solder ingot 15 and the formation of solder bump 14 on the wafer 1 is by means of a re-flow process. The steps comprise of (a) placing the wafer 1 at a sloping position into a solder bath within a vacuum and heating system within a soldering bath 6, and a squeegee 4 is provided to contact the surface of the wafer 1 at the surface position of the solder 3 in the soldering bath 6, and the wafer 1 is being withdrawn and the solder is being squeezed into the photo-resistor opening 21 and the excessive solder is scrapped off; (b) removing the wafer 1 away from the vacuum system and the heating system 5, and after the wafer 1 is being cooled, removing the photo-resistor 2 to retain the solder ingot 15 and further etching the under bump metal 13 layer between the solder ingot 15 such that the solder ingot 15 is isolated as a separate one, and then (c) performing wafer reflow back to a melting furnace to melt the solder ingot into a spherical solder bump.

In accordance with another preferred embodiment, wherein the silk-screening printing process is used, and the steps comprise: (a) horizontally placing the wafer 1 in a vacuuming and heating system 5 and the melted solder 3 being squeezed from one end to the other end of the wafer 1 such that the solder fills the photo-resistor opening 21 on the under bump metal 13 layer; (b) removing the wafer 1 from the vacuuming and heating system 5, and after the wafer 1 is cooled, removing the photo-resistor 2 to retain the solder ingot 0.15 and further etching the under bump metal 13 between the solder ingot 15 such that the solder ingot 15 being isolated as a separate one; (c) performing a wafer 1 re-flow to a melting furnace to melt the solder ingot 15 into a spherical solder bump 14.

In accordance with the present invention, where a vacuuming system and heating system are employed to fabricate solder bump, the drawbacks found in conventional methods can be solved and the present method has improved the yield rate greatly.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. A fabrication method for solder bump pattern of rear section wafer package, comprising the steps of:
(a) pattern-etching the wafer at a passivation layer for the positioning of the solder bump;
(b) depositing the entire under bump metal layer;
(c) performing an opening on a solder pad using a photoresistor of an appropriate thickness;
(d) placing the wafer at a vacuuming system and a heating system, where at this instance, the solder is in a liquid state having a fluidity but without formation of bubbles; and
(e) forming a solder bump pattern at the opening position of the photoresistor of under bump metal of the wafer.

2. The fabrication method of claim 1, wherein the formation of the solder bump on the wafer comprises the steps of:
(a) placing the wafer at a sloping position into a solder bath within a vacuuming system and the surface position of the solder is provided with a squeegee to contact the surface of the wafer, and the wafer being withdrawn and the solder being squeezed into the photo-resistor opening and the excessive solder being scraped off;
(b) removing the wafer from the vacuuming system and the heating system, and after the wafer being cooled, removing the photo-resistor to retain the solder ingot at under bump metal and further etching the under bump metal between the solder ingots so that the solder ingots are isolated into separate one;
(c) performing a wafer re-flow to a melting furnace step to melt the solder ingot into a solder bump having a spherical shape.

3. The fabrication method of claim 1, wherein the formation of solder bump on the wafer via silk-screening printing method comprises the steps of:
(a) horizontally placing the wafer in a vacuuming system and heating system and melted solder at one lateral edge of the wafer being squeezed from one end to the other end of the wafer such that the solder fills the photo-resistor opening position of an under bump metal layer;
(b) removing the wafer from the vacuuming system and the heating system, and after the wafer being cooled, removing the photo-resistor to retain the solder ingot at under bump metal and further etching the under bump metal between the solder ingots so that the solder ingots are isolated into separate one;
(c) performing a wafer re-flow to a melting furnace step to melt the solder ingot into a spherical solder bump.
